(19) United States
(12) Patent Application Publication
(10) Pub. No.: US 2025/0334891 A1
(43) Pub. Date: Oct. 30, 2025

(54) VIBRATION DAMPING DEVICE, EXPOSURE DEVICE, AND EXPOSURE METHOD

(71) Applicant: NIKON CORPORATION, Tokyo (JP)

(72) Inventors: Kensuke TOKUMI, Kumagaya-shi (JP); Kazuki KOJIMA, Kumagaya-shi (JP)

(73) Assignee: NIKON CORPORATION, Tokyo (JP)

(21) Appl. No.: 19/262,731

(22) Filed: Jul. 8, 2025

Related U.S. Application Data
(63) Continuation of application No. PCT/JP2023/013687, filed on Mar. 31, 2023.

(51) Int. Cl. G03F 7/00

(52) U.S. Cl. CPC G03F 7/709; G03F 7/70833

(57) ABSTRACT

A vibration damping device includes a frame body having first and second members that are maintained in a state of being separated from each other in a first direction, a weight disposed between the first and second members, an actuator driving the weight in the first direction between the first and second members, first restraint mechanisms each having one or more leaf springs, the first restraint mechanisms coupling the first member and the weight and allowing the weight to move in the first direction, second restraint mechanisms each having one or more leaf springs, the second restraint mechanisms coupling the second member and the weight and allowing the weight to move in the first direction, and third restraint mechanisms that couple the first and second restraint mechanisms, respectively, and restrain movement of the weight in a direction inclined with respect to a plane perpendicular to the first direction.

### CROSS-REFERENCE TO RELATED APPLICATION

This application is a continuation application of PCT/JP2023/13687, filed on Mar. 31, 2023, the entire contents of which are incorporated herein by reference.

### FIELD

A certain aspect of embodiments described herein relates to a vibration damping device, an exposure device, and an exposure method.

### BACKGROUND

In recent years, liquid crystal display panels have been widely used as display elements of personal computers, televisions, and the like. A liquid crystal display panel is manufactured by forming a circuit pattern of thin film transistors on a plate (glass substrate) by a photolithography method. As a device for the photolithography process, an exposure device is used that projects and exposes an original pattern formed on a mask onto a photoresist layer on a plate through a projection optical system as disclosed in, for example, Japanese Patent Application Publication No. 2015-081993.

In these exposure devices, exposure with high accuracy is required.

### SUMMARY

According to a first aspect of the present disclosure, there is provided a vibration damping device including: a frame body having a first member and a second member that are maintained in a state of being separated from each other in a first direction; a weight disposed between the first member and the second member; an actuator that drives the weight in the first direction between the first member and the second member; a plurality of first restraint mechanisms each having one or more leaf springs, the plurality of first restraint mechanisms coupling the first member and the weight and allowing the weight to move in the first direction; a plurality of second restraint mechanisms each having one or more leaf springs, the plurality of second restraint mechanisms coupling the second member and the weight and allowing the weight to move in the first direction; and a plurality of third restraint mechanisms that couple the plurality of first restraint mechanisms and the plurality of second restraint mechanisms, respectively, and restrain movement of the weight in a direction inclined with respect to a plane perpendicular to the first direction.

According to a second aspect of the present disclosure, there is provided an exposure device that exposes a pattern image of a first object onto a second object, the exposure device including: an illumination optical system that illuminates the first object with exposure light; a projection optical system that projects the exposure light from the first object onto the second object; a chassis that supports the projection optical system;

the above vibration damping device, wherein the vibration damping device is disposed near a position corresponding to an antinode of at least one vibration mode of a plurality of vibration modes generated in the chassis.

According to a third aspect of the disclosure, there is provided an exposure method using the above exposure device, the exposure method including: illuminating the first object with the exposure light using the illumination optical system; and projecting the pattern image of the first object onto the second object using the projection optical system.

The configuration of the embodiments described later may be appropriately improved, and at least some of components may be replaced with other components. Furthermore, the constituent elements whose arrangement is not particularly limited are not limited to the arrangement disclosed in the embodiment, and can be arranged at positions where the functions thereof can be achieved.

### BRIEF DESCRIPTION OF DRAWINGS

FIG. 1 is a schematic view illustrating a configuration of an exposure device according to an embodiment;

FIG. 2 is a perspective view of a vibration damping device according to the embodiment;

FIG. 3A is a side view of the vibration damping device as viewed from the −Y1 side, and FIG. 3B is a side view of the vibration damping device as viewed from the +X1 side;

FIG. 4A is a top view of the vibration damping device, and FIG. 4B is a cross-sectional view taken along line A-A in FIG. 4A; and

FIG. 5 illustrates a first restraint mechanism according to a variation.

### DESCRIPTION OF EMBODIMENTS

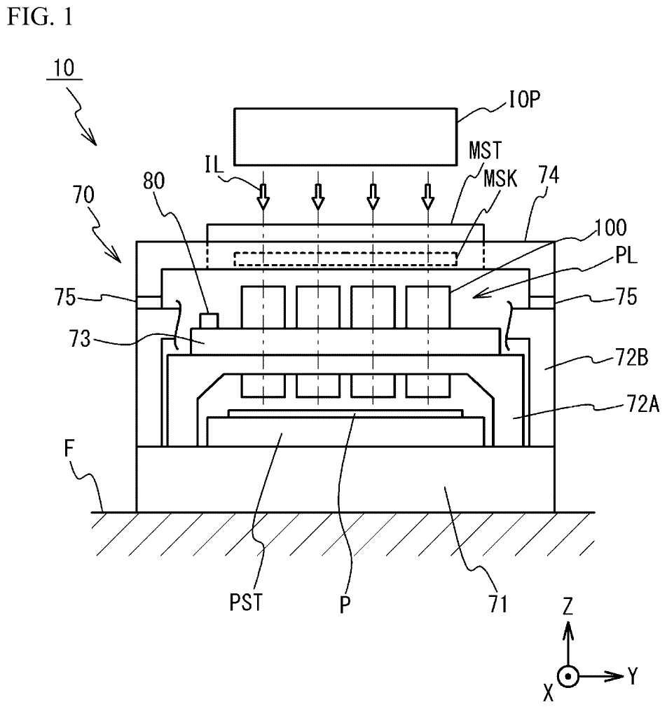

An exposure device 10 according to an embodiment will be described with reference to FIG. 1 to FIG. 4B.

### Configuration of Exposure Device

FIG. 1 is a view schematically illustrating a configuration of the exposure device 10 according to the embodiment.

The exposure device 10 is a scanning stepper (scanner) that transfers a pattern formed on a mask MSK onto a glass substrate (hereinafter referred to as “substrate”) P by driving the mask MSK and the substrate P in the same direction and at the same speed with respect to a projection optical system PL. The substrate P is a rectangular glass substrate used for, for example, liquid crystal display devices (flat panel displays), and at least the length of one side or the diagonal length is equal to or greater than the 500 mm.

In the following description, a direction (scanning direction) in which the mask MSK and the substrate P are driven during scanning exposure is defined as an X-axis direction, a direction orthogonal to the X-axis direction in the horizontal plane is defined as a Y-axis direction, a direction orthogonal to the X-axis and the Y-axis is defined as a Z-axis direction, and rotation (inclination) directions around the X-axis, the Y-axis, and the Z-axis are defined as θx, θy, and θz directions, respectively.

The exposure device 10 includes an illumination optical system IOP, a mask stage MST that holds a mask MSK, the projection optical system PL, a body 70 that supports these components, a substrate stage PST that holds the substrate P, a control system for these components, and the like. The control system performs overall control of each component of the exposure device 10.

The body 70 includes a base (vibration isolator) 71, columns 72A and 72B, an optical surface plate (chassis) 73, a support 74, and a slide guide 75. The base (vibration isolator) 71 is disposed on the floor F, and isolates vibration from the floor F to support the columns 72A, 72B, and the like. The columns 72A and 72B each have a frame shape, and the column 72B is disposed inside the column 72A. The optical surface plate 73 has, for example, a flat plate shape and is fixed to a top portion of the column 72A. The support 74 is supported on the top portion of the column 72B via the slide guide 75. The slide guide 75 includes an air ball lifter and a positioning mechanism, and positions the support 74 (that is, the mask stage MST described later) at an appropriate position in the X-axis direction with respect to the optical surface plate 73.

The illumination optical system IOP is disposed above the body 70. The illumination optical system IOP irradiates the mask MSK with the illumination light IL.

The mask stage MST is supported by the support 74. The mask MSK having a pattern surface (the lower surface in FIG. 1) on which a circuit pattern is formed is fixed to the mask stage MST by, for example, vacuum suction (or electrostatic suction). The mask stage MST is driven in a predetermined stroke in the scanning direction (X-axis direction) by a drive system including, for example, a linear motor, and is finely driven in the non-scanning direction (Y-axis direction and θz direction).

The position information (including rotation information in the θz direction) of the mask stage MST in the XY plane is measured by the interferometer system. The interferometer system emits a measurement beam onto a movable mirror (or a mirror-finished reflection surface (not illustrated)) provided at an end portion of the mask stage MST, and receives reflected light from the movable mirror, thereby measuring the position of the mask stage MST. The measurement results are supplied to a control device (not illustrated), and the control device drives the mask stage MST via a drive system in accordance with the measurement results of the interferometer system.

The projection optical system PL is supported by the optical surface plate 73 below (at the −Z side of) the mask stage MST. The projection optical system PL is configured similarly to the projection optical system disclosed in, for example, U.S. Pat. No. 5,729,331, includes a plurality of (for example, seven) projection optical units 100 (multi-lens projection optical units) in which projection areas of the pattern image of the mask MSK are arranged, for example, in a staggered manner, and forms a rectangular image field having the Y-axis direction as a longitudinal direction. Here, four projection optical units 100 are arranged at predetermined intervals in the Y-axis direction, and the remaining three projection optical units 100 are arranged at predetermined intervals in the Y-axis direction, separated from the four projection optical units 100 at the +X side. As each of the projection optical units 100, for example, a bilateral telecentric isometric system that forms an upright positive image is used. The plurality of projection areas of the projection optical units 100 arranged in a staggered manner are collectively referred to as an exposure area.

When the illumination area on the mask MSK is illuminated with the illumination light IL from the illumination optical system IOP, a projection image (partially erected image) of the circuit pattern of the mask MSK in the illumination area is formed in an irradiation area (exposure area (conjugate with the illumination area)) on the substrate P arranged at the image plane side of the projection optical system PL by the illumination light IL transmitted through the mask MSK via the projection optical system PL. Here, a resist (sensitive agent) is applied to the surface of the substrate P. By synchronously driving the mask stage MST and the substrate stage PST, that is, by driving the mask MSK in the scanning direction (X-axis direction) with respect to the illumination area (illumination light IL) and driving the substrate P in the same scanning direction with respect to the exposure area (illumination light IL), the substrate P is exposed and the pattern of the mask MSK is transferred onto the substrate P.

The substrate stage PST is disposed on the base (vibration isolator) 71 below (at the −Z side of) the projection optical system PL. The substrate P is held on the substrate stage PST via a substrate holder (not illustrated).

The position information (including rotation information (yawing amount (rotation amount θz in the θz direction), pitching amount (rotation amount θx in the 0x direction), and rolling amount (rotation amount θy in the θy direction)) within the XY plane of the substrate stage PST is measured by an interferometer system. The interferometer system emits a measurement beam from the optical surface plate 73 to a movable mirror (or a mirror-finished reflection surface (not illustrated)) provided at the end portion of the substrate stage PST, and receives reflected light from the movable mirror, thereby measuring the position of the substrate stage PST. The measurement results are supplied to a control device (not illustrated), and the control device drives the substrate stage PST in accordance with the measurement results of the interferometer system.

In the exposure device 10, alignment measurement (for example, EGA or the like) is performed prior to exposure, and the substrate P is exposed in the following procedure using the results. First, the mask stage MST and the substrate stage PST are synchronously driven in the X-axis direction in accordance with an instruction from the control device. Thus, scanning exposure is performed on a first shot area on the substrate P. When the scanning exposure of the first shot area is completed, the control device moves (steps) the substrate stage PST to a position corresponding to a second shot area. Then, scanning exposure for the second shot area is performed. Similarly, the control device repeats stepping between shot areas of the substrate P and scanning exposure for the shot areas, and transfers the pattern of the mask MSK to all the shot areas on the substrate P.

In the exposure device 10 described above, the vibration of the optical surface plate 73 during scanning exposure affects the exposure accuracy (the accuracy of the pattern formed on the photosensitive material of the substrate P). The inventors have found by simulation that a plurality of vibration modes are generated in the optical surface plate 73 during scanning exposure. Possible causes of the vibration of the optical surface plate 73 include, for example, vibration caused by the operation of the exposure device 10 itself and vibration caused by the surrounding environment of the exposure device 10.

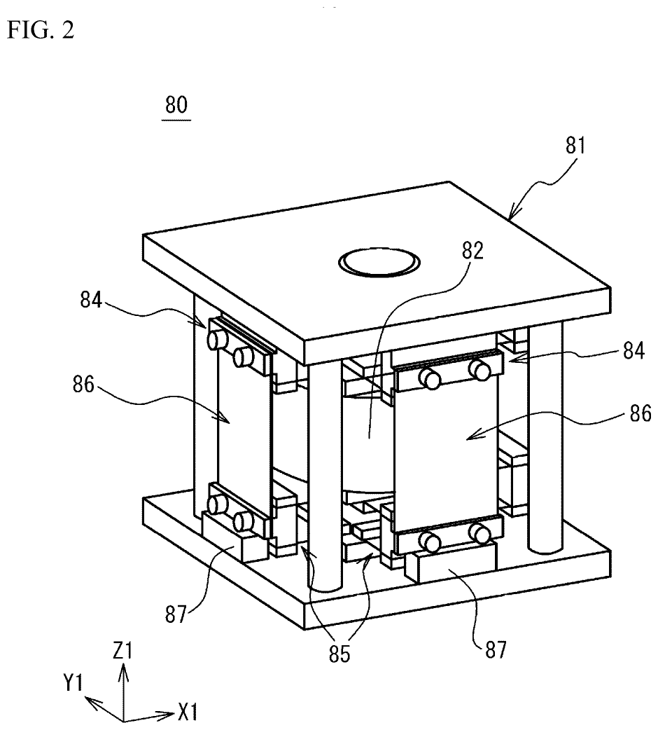

Therefore, in the present embodiment, in order to reduce the vibration of the optical surface plate 73 holding the projection optical system PL, one or a plurality of vibration damping devices 80 are installed on the optical surface plate 73. The structure of the vibration damping device 80 according to the present embodiment will be described in detail with reference to FIG. 2 to FIG. 4B. In FIG. 2 to FIG. 4B, a direction in which a weight 82 described later moves is defined as a Z1 direction, and directions in which sides of a lower base portion 81b having a planar rectangular shape described later extend in a plane perpendicular to the Z1 direction are defined as an X1 direction and a Y1 direction. The X1 direction, the Y1 direction, and the Z1 direction are orthogonal to each other.

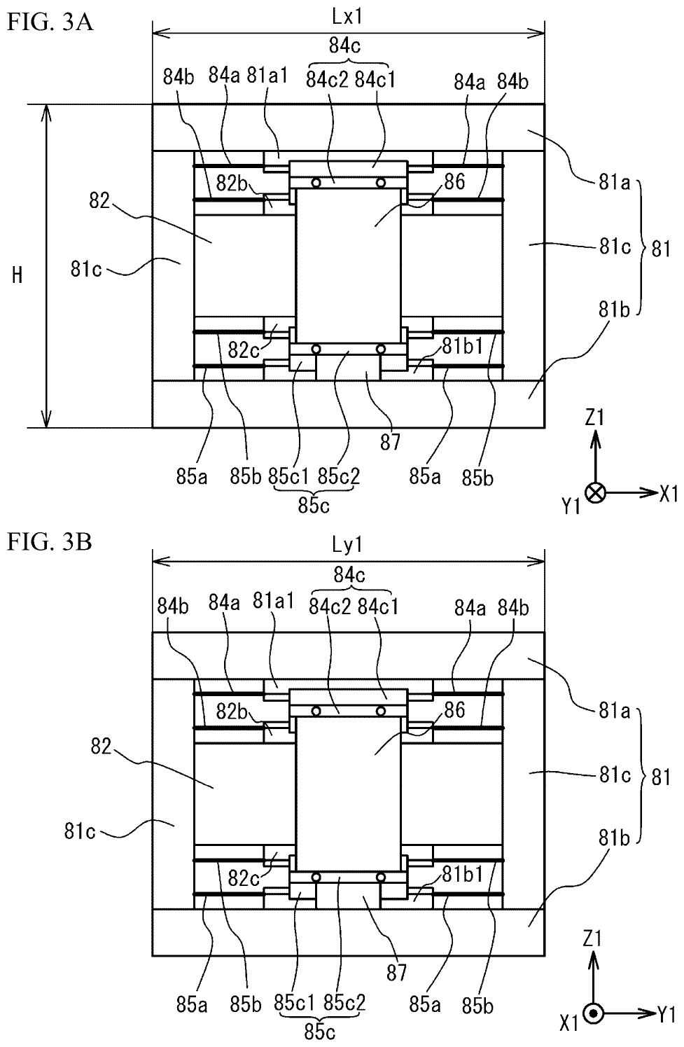

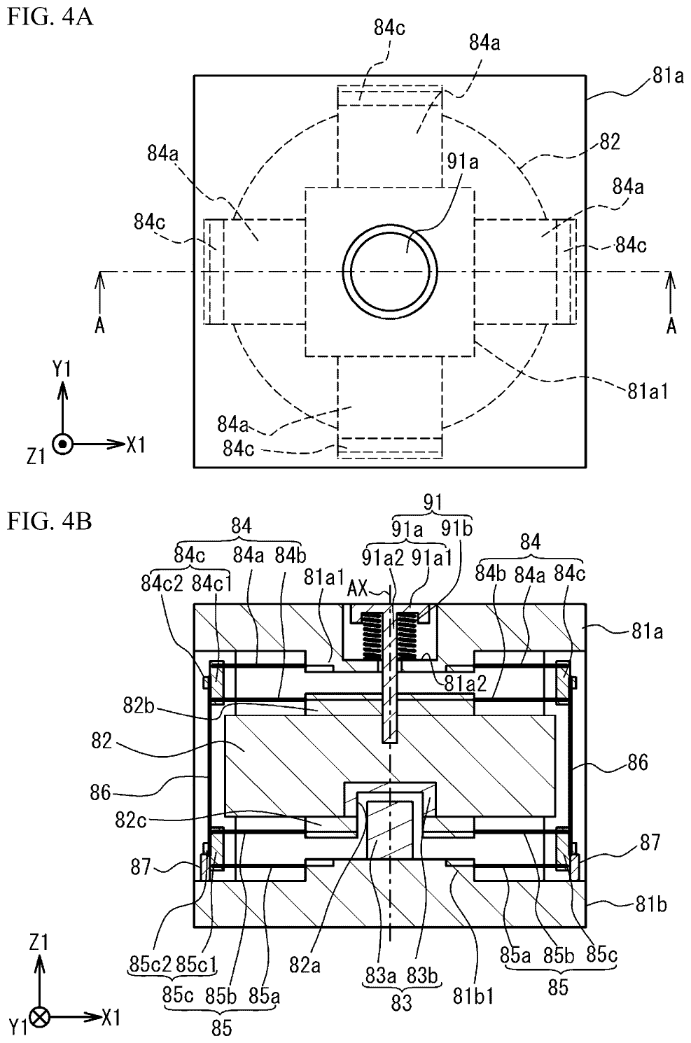

FIG. 2 is a perspective view of the vibration damping device 80 according to the present embodiment. FIG. 3A is a side view of the vibration damping device 80 as viewed from the −Y1 side, and FIG. 3B is a side view of the vibration damping device 80 as viewed from the +X1 side. FIG. 4A is a top view of the vibration damping device 80, and FIG. 4B is a cross-sectional view taken along line A-A in FIG. 4A. In FIG. 4A, some of the components of the vibration damping device 80 are indicated by broken lines.

As illustrated in FIG. 2, the vibration damping device 80 includes a frame body 81, the weight 82 disposed inside the frame body 81, a plurality of first restraint mechanisms 84 that couple the frame body 81 and the weight 82 and allow the movement of the weight 82 in the Z1 direction, a plurality of second restraint mechanisms 85 that couple the frame body 81 and the weight 82 and allow the movement of the weight 82 in the Z1 direction, and a plurality of leaf springs (third restraint mechanisms) 86 that couple the plurality of first restraint mechanisms 84 and the plurality of second restraint mechanisms 85, respectively, and restrain the movement of the weight 82 in a direction inclined with respect to a plane perpendicular to the Z1 direction.

As illustrated in FIG. 3A and FIG. 3B, the frame body 81 includes an upper base portion (first member) 81a, the lower base portion (second member) 81b, and a plurality of support members 81c that couple the upper base portion 81a and the lower base portion 81b. The plurality of support members 81c maintain the upper base portion 81a and the lower base portion 81b in a state of being separated from each other in the Z1 direction.

As illustrated in FIG. 4B, the weight 82 is disposed between the upper base portion 81a and the lower base portion 81b. The weight 82 has, for example, a cylindrical shape. A recess 82a is formed on the −Z1-side surface of the weight 82, and a part of a stator 83a of a voice coil motor (VCM) 83 is accommodated in the recess 82a.

The stator 83a of the VCM 83 is fixed to the lower base portion 81b, and a mover 83b is fixed to the weight 82. Thus, the VCM 83 drives the weight 82 in the Z1 direction between the upper base portion 81a and the lower base portion 81b.

In the present embodiment, four first restraint mechanisms 84 and four second restraint mechanisms 85 are provided. The four first restraint mechanisms 84 couple the upper base portion 81a and the weight 82 and allow the weight 82 to move in the Z1 direction. The plurality of first restraint mechanisms 84 restrain the movement of the weight 82 in a plane perpendicular to the Z1 direction and the movement of the weight 82 around the Z1 axis (axis parallel to the Z1 direction). As illustrated in FIG. 4A, in the present embodiment, the four first restraint mechanisms 84 are arranged at intervals of 90 degrees in the circumferential direction of a circle centered on the central axis AX of the weight 82. Accordingly, for example, even when the vibration damping device 80 is installed with the X1 direction or the Y1 direction parallel to the gravity direction (with the Z1 direction parallel to the horizontal direction), the movement of the weight 82 in the Z1 direction can be allowed while the movement of the weight 82 in the plane perpendicular to the Z1 direction and the movement of the weight 82 around the Z1 axis are restrained.

Each first restraint mechanism 84 includes a first leaf spring (first leaf spring portion) 84a, a second leaf spring (second leaf spring portion) 84b, and a first coupling portion 84c. A first end of the first leaf spring 84a is connected to a fixing portion 81a1 of the upper base portion 81a, and a second end of the first leaf spring 84a is connected to a first fixing portion 84c1 of the first coupling portion 84c. A first end of the second leaf spring 84b is connected to an upper fixing portion 82b that is fixed to the +Z1-side end surface of the weight 82, and a second end of the second leaf spring 84b is connected to the first fixing portion 84c1 of the first coupling portion 84c. By coupling the upper base portion 81a and the weight 82 using two leaf springs whose second ends are connected to each other and that extend in parallel in this manner, that is, by coupling two leaf springs in a U-shape, it is possible to make the movable length (stroke) of the weight 82 in the Z1 direction longer than in the case where the upper base portion Z1 and the weight 82 are coupled using one leaf spring having the same length.

The four second restraint mechanisms 85 couples the lower base portion 81b and the weight 82, and allow the weight 82 to move in the Z1 direction. The four second restraint mechanisms 85 restrain the movement of the weight 82 in a plane perpendicular to the Z1 direction and the movement of the weight 82 around the Z1 axis. The four second restraint mechanisms 85 are disposed opposite the four first restraint mechanisms 84 in the Z1 direction.

Each second restraint mechanism 85 includes a third leaf spring (third leaf spring portion) 85a, a fourth leaf spring (fourth leaf spring portion) 85b, and a second coupling portion 85c. A first end of the third leaf spring 85a is connected to a fixing portion 81b1 of the lower base portion 81b, and a second end of the third leaf spring 85a is connected to a first fixing portion 85c1 of the second coupling portion 85c. A first end of the fourth leaf spring 85b is connected to a lower fixing portion 82c that is fixed to the −Z1-side end surface of the weight 82, and a second end of the fourth leaf spring 85b is connected to the first fixing portion 85c1 of the second coupling portion 85c. By coupling the lower base portion 81b and the weight 82 using two leaf springs whose second ends are connected to each other and that extend in parallel in this manner, it is possible to make the movable length (stroke) of the weight 82 in the Z1 direction longer than in the case where the lower base portion 81b and the weight 82 are coupled using one leaf spring having the same length.

The thickness of each of the first leaf spring 84a, the second leaf spring 84b, the third leaf spring 85a, and the fourth leaf spring 85b is determined based on the weight of the weight 82 and the frequency to be damped.

The leaf spring (third restraint mechanism) 86 couples the first restraint mechanism 84 and the second restraint mechanism 85, and restrains the movement of the weight 82 in a direction inclined with respect to a plane perpendicular to the Z1 direction. In the present embodiment, a first end of the leaf spring 86 is connected to a second fixing portion 84c2 of the first coupling portion 84c included in the first restraint mechanism 84, and a second end of the leaf spring 86 is connected to a second fixing portion 85c2 of the second coupling portion 85c included in the second restraint mechanism 85.

A vibration absorbing member 87 is provided between the lower base portion 81b and the second fixing portion 85c2 of the second coupling portion 85c. In the present embodiment, the −Z1-side end portion of the vibration absorbing member 87 is fixed to the lower base portion 81b. The +Z1-side end portion of the vibration absorbing member 87 is not fixed to any member. Since the second fixing portion 85c2 of the second coupling portion 85c is a part of the second restraint mechanism 85, it can be said that the vibration absorbing member 87 is installed between the lower base portion 81b and the second restraint mechanism 85. Further, since the second fixing portion 85c2 fixes the leaf spring 86, it can be said that the vibration absorbing member 87 is installed between the lower base portion 81b and the leaf spring 86. For example, the vibration absorbing member 87 may be disposed between the lower base portion 81b and the first fixing portion 85c1 of the second coupling portion 85c.

The vibration absorbing member 87 absorbs vibration (resonance) of the leaf spring 86 caused by an unwanted vibration mode generated in the vibration damping device 80. The material of the vibration absorbing member 87 is a material that attenuates vibration by converting kinetic energy due to vibration into energy such as heat or sound. For example, a member having viscoelasticity (polymeric polymers, viscous-fluids/fine-particle filled structures) or the like may be used. Here, an example of the polymeric polymer is Sorbothane (registered trademark). An example of the member using the viscous fluid is a damper using oil/water.

The vibration damping device 80 further includes a self-weight compensation mechanism 91 that compensates for the self-weight of the weight 82. The self-weight compensation mechanism 91 includes a support portion 91a and a compression coil spring 91b. The support portion 91a has a substantially T-shaped cross section and includes a spring engagement portion 91a1 intersecting the Z1 direction and an extension portion 91a2 extending from the spring engagement portion 91a1 in the −Z1 direction. The extension portion 91a2 is coupled to the weight 82.

A first end of the compression coil spring 91b is in contact with the bottom surface of a recess 81a2 formed in the upper base portion 81a, and a second end of the compression coil spring 91b is in contact with the spring engagement portion 91a1 of the support portion 91a. The spring generating force of the compression coil spring 91b is set to a spring generating force such that the first leaf spring 84a, the second leaf spring 84b, the third leaf spring 85a, and the fourth leaf spring 85b are parallel to a plane perpendicular to the Z1 direction in a state where the weight 82 is at rest. That is, when the weight 82 is at rest, the position of the weight 82 is held at the center of the stroke. Further, it is desirable that the spring coefficient of the compression coil spring 91b is as small as possible in order to reduce the loss of thrust of the VCM 83.

This reduces the loss of thrust of the VCM 83 due to the expansion and contraction of the compression coil spring 91b, while compensating for the self-weight of the weight 82 in a state where the VCM 83 is not under load. In addition, it is possible to secure a stroke when the weight 82 is driven. Further, the load on the VCM 83 when the weight 82 is driven can be reduced.

Each of the length Lx1 in the X1 direction and the length Ly1 in the Y1 direction of the vibration damping device 80 is, for example, 120 mm to 130 mm, and the height H of the vibration damping device 80 is, for example, 123 mm to 129 mm. The size of the vibration damping device 80 is not limited to this.

In the present embodiment, the vibration damping device 80 is installed on the optical surface plate 73 so that the moving direction (Z1 direction) of the weight 82 is aligned with the direction of gravity (Z direction in FIG. 1). That is, the vibration damping device 80 is installed on the optical surface plate 73 so that the lower base portion 81b is in contact with the upper surface of the optical surface plate 73.

The vibration damping device 80 is preferably provided at a position other than the node of at least one vibration mode to be damped among a plurality of vibration modes generated in the optical surface plate 73. This is because, in a case where the vibration damping device 80 is provided at the node of the vibration mode, the vibration damping device 80 does not contribute to the attenuation of the vibration mode even when the vibration damping device 80 is driven. The vibration damping device 80 is more preferably provided in a region where it can contribute to the attenuation of the vibration mode, and further preferably provided in the vicinity of the antinode of the vibration mode in which the vibration displacement is particularly large. By moving the weight 82 in the Z1 direction at a frequency corresponding to the frequency of the vibration mode to be damped by the VCM 83, it is possible to reduce the vibration at the frequency of the vibration mode to be damped among the vibration modes generated in the optical surface plate 73.

Further, for example, when two vibration modes of the vibration modes generated in the optical surface plate 73 are to be damped, the vibration damping device 80 is preferably installed in a range where a part other than the node of one vibration mode and a part other than the node of the other vibration mode overlap each other. The vibration damping device 80 is more preferably provided in a region where the vibration damping device 80 can contribute to attenuation of the two vibration modes, and particularly when the antinodes, where the vibration displacement is large, of the two vibration modes are close to each other, the vibration damping device 80 is further preferably provided in the vicinity of the antinodes of the two vibration modes (for example, an intermediate position between positions where the antinodes of the two vibration modes are generated). The VCM 83 moves the weight 82 in the Z1 direction at frequencies corresponding to the frequencies of the two vibration modes, respectively, thereby inhibiting the optical surface plate 73 from vibrating at the frequencies of the two vibration modes. This can improve the exposure accuracy of the exposure device 10. Further, the weight 82 can be significantly reduced in weight as compared with the case where a tuned mass damper is used.

The vibration damping device 80 may be installed at one location or a plurality of locations.

As described above in detail, according to the present embodiment, the vibration damping device 80 includes the frame body 81 having the upper base portion 81a and the lower base portion 81b that are maintained in a state of being separated from each other in the Z1 direction, the weight 82 disposed between the upper base portion 81a and the lower base portion 81b, and the VCM 83 that drives the weight 82 in the Z1 direction between the upper base portion 81a and the lower base portion 81b. The vibration damping device 80 further includes a plurality of the first restraint mechanisms 84 each having the first leaf spring 84a and the second leaf spring 84b, which couple the upper base portion 81a and the weight 82 and allow the weight 82 to move in the Z1 direction, a plurality of the second restraint mechanisms 85 each having the third leaf spring 85a and the fourth leaf spring 85b, which couple the lower base portion 81b and the weight 82 and allow the weight 82 to move in the Z1 direction, and a plurality of the leaf springs 86 that couple the plurality of the first restraint mechanisms 84 and the plurality of the second restraint mechanisms 85, respectively, and restrain the weight 82 from moving in a direction inclined with respect to a plane perpendicular to the Z1 direction.

Additionally, according to the present embodiment, the plurality of the first restraint mechanisms 84 restrain the movement of the weight 82 in the plane perpendicular to the Z1 direction and the movement of the weight 82 around the Z1 axis, and the plurality of the second restraint mechanisms 85 restrain the movement of the weight 82 in the plane perpendicular to the Z1 direction and the movement of the weight 82 around the Z1 axis.

Examples of the mechanism for allowing the movement of the weight 82 in the Z1 direction while restraining the movement of the weight 82 in the plane perpendicular to the Z1 direction and the movement of the weight 82 around the Z1 axis include a sliding guide such as an LM guide and an air guide. However, in the sliding guide, wear of the guide surface progresses due to repeated bending stress caused by vibration of the sliding guide, and it is difficult to secure stable vibration damping performance for a long period of time because characteristics (for example, sliding friction resistance) change because of the wear. In addition, maintenance such as lubrication is required. In addition, although the characteristics of a non-contact guide such as an air guide do not change because the non-contact guide is not worn, the non-contact guide requires power (compressed air) during use and it is difficult to secure a load capacity (allowable load).

In contrast, in the present embodiment, since the leaf springs are used as mechanisms for allowing the movement of the weight 82 in the Z1 direction while restraining the movement of the weight 82 in the plane perpendicular to the Z1 direction and the movement of the weight 82 around the Z1 axis, it is possible to secure stable vibration damping performance for a long period of time without wear. Further, maintenance is easy. Further, since the leaf spring is inexpensive compared to the LM guide and the air guide, the component cost of the vibration damping device 80 can also be reduced.

In the present embodiment, each of the plurality of the first restraint mechanisms 84 includes the first leaf spring 84a connected to the upper base portion 81a, the second leaf spring 84b connected to the weight 82, and the first coupling portion 84c coupling the first leaf spring 84a and the second leaf spring 84b. Each of the plurality of the second restraint mechanisms 85 includes the third leaf spring 85a connected to the lower base portion 81b, the fourth leaf spring 85b connected to the weight 82, and the second coupling portion 85c coupling the third leaf spring 85a and the fourth leaf spring 85b. As illustrated in FIG. 4B, by connecting two leaf springs in a U-shape, the distance (stroke) by which the weight 82 can move can be made longer than in the case of using one leaf spring having the same length. The two leaf springs may be connected in a V-shape instead of the U-shape.

In the present embodiment, the vibration damping device 80 includes a plurality of the vibration absorbing members 87 that absorb the vibrations of the plurality of the leaf springs 86, respectively. This allows the resonance of the unwanted vibration modes generated in the vibration damping device 80 to be attenuated and inhibited.

In the present embodiment, the vibration damping device 80 includes the self-weight compensation mechanism 91 that compensates for the self-weight of the weight 82. This allows the position of the weight 82 to be held at the center of the stroke when the weight 82 is at rest, thus securing the stroke when the weight 82 is driven. Further, when the weight 82 is driven, the load applied to the VCM 83 can be reduced.

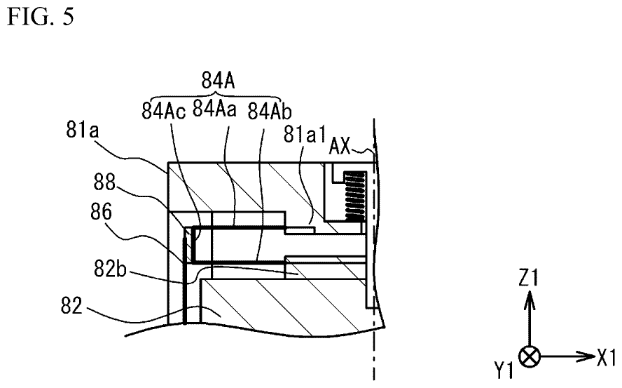

In the above embodiment, the first restraint mechanism 84 includes the first leaf spring 84a, the second leaf spring 84b, and the first coupling portion 84c, but the first restraint mechanism 84 may be realized by one leaf spring. FIG. 5 illustrates a first restraint mechanism 84A according to a variation. The first restraint mechanism 84A includes a first leaf spring portion 84Aa, a second leaf spring portion 84Ab, and a coupling portion 84Ac that couples the first leaf spring portion 84Aa and the second leaf spring portion 84Ab, and the first leaf spring portion 84Aa, the second leaf spring portion 84Ab, and the coupling portion 84Ac are formed of one leaf spring. That is, in the variation, the first restraint mechanism 84A is realized by bending one leaf spring into a U-shape. The upper base portion 81a and the weight 82 may be coupled to each other by such a structure. In this case, for example, the leaf spring 86 may be soldered to the coupling portion 84Ac of the first restraint mechanism 84A, or the first restraint mechanism 84A and the leaf spring 86 may be connected by providing a fixing member 88 as illustrated in FIG. 5. The same applies to the second restraint mechanism 85. The first restraint mechanism 84A may be realized by bending one leaf spring into a V-shape instead of a U-shape.

In the above embodiment, the leaf spring 86 is used as the third restraint mechanism that couples the first restraint mechanism 84 and the second restraint mechanism 85, but this does not intend to suggest any limitation. The mechanism for coupling the first restraint mechanism 84 and the second restraint mechanism 85 may be a member other than the leaf spring as long as the member does not expand and contract in the Z1 direction.

In the above embodiment, the vibration damping device 80 includes the four first restraint mechanisms 84 and the four second restraint mechanisms 85, but this does not intend to suggest any limitation. In a case where the vibration damping device 80 is installed with the Z1 direction parallel to the gravity direction, at least three first restraint mechanisms 84 and at least three second restraint mechanisms 85 are provided. The number of the first restraint mechanisms 84 and the number of the second restraint mechanisms 85 may be five or more.

In the above embodiment, a first end of the vibration absorbing member 87 is fixed to the lower base portion 81b, but this does not intend to suggest any limitation. The first end of the vibration absorbing member 87 may be fixed to a separate member fixed to the lower base portion 81b. Further, the first end of the vibration absorbing member 87 may be fixed to the support member 81c coupling the upper base portion 81a and the lower base portion 81b. Further, the first end of the vibration absorbing member 87 may be fixed to, for example, the optical surface plate 73 or another member fixed to the optical surface plate 73, instead of the component of the vibration damping device 80.

In the above embodiment, the vibration absorbing member 87 is provided between the lower base portion 81b and the leaf spring 86, but the vibration absorbing member 87 may be provided between the upper base portion 81a and the leaf spring 86, or between the upper base portion 81a and the first restraint mechanism 84. A second end of the vibration absorbing member 87 may be coupled to the end of the leaf spring 86.

In the above embodiment, the weight 82 is driven in the Z1 direction by the VCM 83, but this does not intend to suggest any limitation. A piezoelectric element, a linear motor, or the like may be used instead of the VCM 83.

In the above embodiment, an example in which the vibration damping device 80 is installed on the optical surface plate 73 has been described, but this does not intend to suggest any limitation, and the vibration damping device 80 can be installed on any component in the exposure device 10 whose vibration is to be reduced. The vibration damping device 80 may be installed in a device other than the exposure device 10.

In the above embodiment, the case where the vibration damping device 80 is installed so that the Z1 direction of the vibration damping device 80 is parallel to the gravity direction has been described, but the vibration damping device 80 may be installed so that the Z1 direction of the vibration damping device 80 is parallel to the horizontal direction (the X1 direction or the Y1 direction is in parallel to the gravity direction) according to the direction of the vibration generated in the component. The vibration damping device 80 may be installed in a state where the Z1 direction is inclined with respect to the gravity direction.

When the vibration damping device 80 is used in a state where the X1 direction

or the Y1 direction is parallel to the gravity direction, it is difficult to increase the weight of the weight 82 if a non-contact guide such as an air guide is used as a mechanism for allowing the movement of the weight 82 in the Z1 direction while restraining the movement of the weight 82 in the plane perpendicular to the Z1 direction and the movement of the weight 82 around the Z1 axis. In the present embodiment, since the leaf spring is used as a mechanism for allowing the movement of the weight 82 in the Z1 direction while restraining the movement of the weight 82 in the plane perpendicular to the Z1 direction and the movement of the weight 82 around the Z1 axis, it is possible to increase the weight of the weight 82.

In a case where the vibration damping device 80 is installed so that the Z1 direction is parallel to the horizontal direction (the X1 direction or the Y1 direction is parallel to the gravity direction), the self-weight compensation mechanism 91 may be omitted.

Further, in the above embodiment, the case has been described where the exposure device 10 is a scanning stepper, but this does not intend to suggest any limitation, and the exposure device 10 may be a static exposure device such as a stepper, or a reduction projection exposure device of a step-and-stitch type that combines a shot area and a shot area.

Further, although the case where the pattern image of the mask MSK of the exposure device 10 is scanned and exposed onto the substrate P has been described, a spatial light modulator having a plurality of spatial light modulation elements may be used instead of the mask MSK. In this case, the pattern image generated by the spatial light modulator is scanned and exposed on the substrate P.

The above-described embodiments are preferred examples of the present disclosure. However, the present invention is not limited to this, and various modifications can be made without departing from the scope of the present disclosure.

What is claimed is:

1. A vibration damping device comprising:
a frame body having a first member and a second member that are maintained in a state of being separated from each other in a first direction;
a weight disposed between the first member and the second member;
an actuator that drives the weight in the first direction between the first member and the second member;
a plurality of first restraint mechanisms each having one or more leaf springs, the plurality of first restraint mechanisms coupling the first member and the weight and allowing the weight to move in the first direction;
a plurality of second restraint mechanisms each having one or more leaf springs, the plurality of second restraint mechanisms coupling the second member and the weight and allowing the weight to move in the first direction; and
a plurality of third restraint mechanisms that couple the plurality of first restraint mechanisms and the plurality of second restraint mechanisms, respectively, and restrain movement of the weight in a direction inclined with respect to a plane perpendicular to the first direction.

2. The vibration damping device according to claim 1,
wherein the plurality of first restraint mechanisms restrain movement of the weight in the plane perpendicular to the first direction and movement of the weight around a first axis parallel to the first direction; and
wherein the plurality of second restraint mechanisms restrain the movement of the weight in the plane perpendicular to the first direction and the movement of the weight around the first axis.

3. The vibration damping device according to claim 1,
wherein each of the plurality of first restraint mechanisms includes:
a first leaf spring portion connected to the first member;
a second leaf spring portion connected to the weight; and
a first coupling portion that couples the first leaf spring portion and the second leaf spring portion, and
wherein each of the plurality of second restraint mechanisms includes:
a third leaf spring portion connected to the second member;
a fourth leaf spring portion connected to the weight; and
a second coupling portion that couples the third leaf spring portion and the fourth leaf spring portion.

4. The vibration damping device according to claim 3,
wherein the first leaf spring portion, the second leaf spring portion, and the first coupling portion are formed of one leaf spring, and
wherein the third leaf spring portion, the fourth leaf spring portion, and the second coupling portion are formed of one leaf spring.

5. The vibration damping device according to claim 1,
wherein the plurality of first restraint mechanisms are disposed at least three locations in a circumferential direction of a circle centered on a first axis parallel to the first direction, and
wherein the plurality of second restraint mechanisms are disposed so as to face the plurality of first restraint mechanisms in the first direction, respectively.

6. The vibration damping device according to claim 1, wherein each of the plurality of third restraint mechanisms is a leaf spring.

7. The vibration damping device according to claim 1, wherein each of the plurality of third restraint mechanisms is a member that does not expand or contract in a direction in which the weight moves.

8. The vibration damping device according to claim 1, further comprising:
a plurality of vibration absorbing members that absorb vibration of the plurality of third restraint mechanisms, respectively.

9. The vibration damping device according to claim 8, wherein the plurality of vibration absorbing members are provided between the first member and the plurality of first restraint mechanisms, between the second member and the plurality of second restraint mechanisms, between the first member and the plurality of third restraint mechanisms, or between the second member and the plurality of third restraint mechanisms, respectively.

10. The vibration damping device according to claim 1, further comprising:
a self-weight compensation mechanism that compensates for the self-weight of the weight.

11. The vibration damping device according to claim 1, wherein the actuator is a voice coil motor.

12. The vibration damping device according to claim 1, wherein a thickness of the one or more leaf springs included in each of the plurality of first restraint mechanisms and a thickness of the one or more leaf springs included in each of the plurality of second restraint mechanisms are determined based on a weight of the weight and a frequency to be damped.

13. The vibration damping device according to claim 1, further comprising a support member that couples the first member and the second member.

14. An exposure device that exposes a pattern image of a first object onto a second object, the exposure device comprising:
an illumination optical system that illuminates the first object with exposure light;
a projection optical system that projects the exposure light from the first object onto the second object;
a chassis that supports the projection optical system;
the vibration damping device according to claim 1,
wherein the vibration damping device is disposed near a position corresponding to an antinode of at least one vibration mode of a plurality of vibration modes generated in the chassis.

15. The exposure device according to claim 14, wherein the second object is a photosensitive substrate, at least a length of one side or a diagonal length of the photosensitive substrate being equal to or greater than 500 mm.

16. The exposure device according to claim 14, wherein the actuator moves the weight in the first direction at a frequency corresponding to a frequency of the at least one vibration mode.

17. An exposure method using the exposure device according to claim 14, the exposure method comprising:
illuminating the first object with the exposure light using the illumination optical system; and
projecting the pattern image of the first object onto the second object using the projection optical system.
